(19) United States
(12) Patent Application Publication
(10) Pub. No.: US 2023/0213680 A1
(43) Pub. Date: Jul. 6, 2023

(54) METHOD FOR LOCALIZING AN OBJECT IN THE SURROUNDINGS OF AN APPARATUS GENERATING A STRAY MAGNETIC FIELD, ARRANGEMENT AND OBJECT

(71) Applicant: Siemens Healthcare GmbH, Erlangen (DE)

(72) Inventors: Marcel RUF, Langensendelbach (DE); Felix Horn, Roth (DE); Verena Schmidt, Erbenforf (DE)

(73) Assignee: Siemens Healthcare GmbH, Erlangen (DE)

(21) Appl. No.: 18/149,223

(22) Filed: Jan. 3, 2023

(30) Foreign Application Priority Data
Jan. 5, 2022 (EP) 22150337.8

(51) Int. Cl. G01V 3/08

(52) U.S. Cl. CPC G01V 3/081; G01R 33/28

(57) ABSTRACT

A method for localizing an object in the surroundings of an apparatus generating a stray magnetic field, wherein the object has a sensor arrangement including at least one magnetic field sensor, the method comprising: ascertaining at least one item of object information based on (i) stray-field information describing the spatial profile of the stray magnetic field at least within a region and (ii) at least one measured value measured with the sensor arrangement describing a location-dependent property of the stray magnetic field, the at least one item of object information describing at least one of the position or orientation of the object in the region.

### CROSS-REFERENCE TO RELATED APPLICATION(S)

The present application claims priority under 35 U.S.C. § 119 to European Patent Application No. 22150337.8, filed Jan. 5, 2022, the entire contents of which are incorporated herein by reference.

### FIELD

One or more example embodiments of the present invention relate to a method for localizing an object in the surroundings of an apparatus generating a stray magnetic field. Furthermore, one or more example embodiments of the present invention relate to an arrangement comprising an apparatus, an object and a control facility and an object for such an arrangement.

### BACKGROUND

An apparatus generating a stray magnetic field can, for example, be a magnetic resonance imaging (MRI) scanner which inherently generates a strong magnetic field in its interior. Herein, despite careful shielding or shimming measures, such MRI scanners are generally also surrounded by a stray magnetic field.

### SUMMARY

In the surroundings of such MRI scanners, there may be a variety of applications in which localization of an object is required. For example, self-moving objects, for example autonomously driven patient benches or the like, can depend on a determination of position and orientation in order to perform the autonomous driving operation. However, herein, in particular in the surroundings of apparatuses that generate a stray magnetic field, the problem arises that the sensors required for localization are exposed to the stray magnetic field during the independent movement. Herein, in order to avoid functional impairment of standard sensors, special screening measures or the like may be required and this increases the outlay for providing such a system.

There is therefore a requirement for an improved method for localizing an object in the surroundings of an apparatus generating a stray magnetic field.

To achieve at least this object, one or more example embodiments of the present invention provide a method of the type mentioned in the introduction that the object has a sensor facility (sensor or sensor arrangement) comprising at least one magnetic field sensor, wherein, in dependence on stray-field information describing the spatial profile of the stray field at least within a region and at least one measured value measured with the sensor facility describing a location-dependent property of the stray field, at least one item of object information describing the position and/or orientation of the object in the region is ascertained.

Therefore, the object to be localized comprises a sensor facility, which has one or more magnetic field sensors. This sensor facility can be used to ascertain at least one measured value describing a location-dependent and in particular vectorial property of the stray field. Additionally taking account of the stray-field information describing the spatial profile of the stray field or the spatial profile of the property of the stray field that can also be captured by the sensor facility enables the position and/or orientation of the object to be ascertained in the region as object information. Herein, it is sufficient for the stray-field information to describe the stray field at least within a limited region in which localization is to take place.

According to one or more example embodiments of the present invention, the apparatus generating a stray magnetic field can be a magnetic resonance imaging facility (MRI facility or MRI device). According to one or more example embodiments of the present invention, the object can be a patient bench and/or an accessory assigned to an MRI facility. However, it is also possible for the method to be used with other types of apparatuses generating a stray magnetic field and/or other types of objects.

One or more example embodiments of the present invention are based on the knowledge that the actually undesirable stray field of an MRI facility, which is present outside the patient receptacle, also referred to as the bore, and hence in the environment of the MRI facility, can advantageously be used for the localization of an object. The profile of such a stray field is known in principle for an MRI facility and can, for example, be calculated and/or ascertained by measurement.

The stray-field information can describe the spatial profile of the stray field at least within a region extending in the immediate environment of the MRI facility, for example within a treatment room in which the MRI facility is arranged. In a clinical MRI facility the stationary stray magnetic field is in particular stationary and can, for example, have magnetic flux densities of up to several 100 mT.

The determination of the position or orientation of the object with the aid of the stray magnetic field and the magnetic field sensor enables the implementation of further functionalities of the object that require a determination of the position and/or orientation of the object, on the basis of the ascertained object information. For example, as will be described in more detail below, an autonomous or at least semi-autonomous driving maneuver for a patient bench, for example an auto-docking function, i.e., the independent approach and docking of a patient bench with an MRI facility starting from a variable starting position, can also be advantageously implemented with the aid of the object information ascertained according to one or more example embodiments of the present invention.

Compared to the use of conventional standard sensors for ascertaining distance, position and/or orientation, such as, for example, radar and lidar sensors, ultrasonic sensors, two-dimensional or three-dimensional camera arrangements, tactile sensors, capacitive proximity sensors or the like, the use of a magnetic field sensor in combination with the stray-field information describing the spatial profile of the stray field offers numerous advantages.

Compared to radiating distance sensors, such as radar sensors, lidar sensors or ultrasonic sensors, the use of the magnetic field sensor has the advantage that the sensor operation is passive and hence no electromagnetic or acoustic waves have to be radiated. Due to the passive measuring principle, unlike the case with radar-based applications, no radio approvals or other regulatory approvals are required, so that the effort and costs for implementing the method can be significantly reduced. Furthermore, unlike the case with a lidar sensor for example, a magnetic field sensor is not subject to any safety requirements arising from laser protection classes or the like. Magnetic field sensors and the electronics that may be used to evaluate the magnetic field sensors are comparatively inexpensive and can be implemented in different configurations or housing types or the like.

Furthermore, the use of the magnetic field sensor makes it possible to determine a position directly, which is inherently complex with distance sensors, since in some circumstances, a starting position is initially unknown and hence, for example in the context of path planning for a movement of the object, first has to be ascertained from the distances to further objects or the like.

Camera systems for position determination are comparatively complex to implement and, in addition to one or more cameras, require a comparatively complex evaluation of the recorded image data. Furthermore, they require an unobstructed view, which, in particular in the surroundings of an MRI facility, can be impaired by ceilings, hoses or the like. On the other hand, a magnetic field sensor and the evaluation of the measured values ascertained thereby can be implemented with little effort and hence inexpensively. In addition, the stray field can be captured by the magnetic field sensor in a manner substantially unimpeded by third-party objects.

Tactile sensors require direct contact with a third-party object for position determination, which makes them less suitable for in particular stationary localization or for localization during a movement operation. However, the interaction between the stray field and the at least one magnet sensor, which is used according to one or more example embodiments of the present invention for localization, is advantageously not dependent on third-party objects.

Capacitive proximity sensors have only a comparatively short range and are hence not suitable for localization in free space, in particular in the context of a movement operation involving movement over several meters, which can be necessary in the surroundings of an MRI facility. In contrast, the use of the stray field and the magnetic sensor also enables localization to be carried out at greater distances from the apparatus and/or from third-party objects, in particular since, for example, in the case of an MRI facility, there is a comparatively high stray field which can therefore also be detected at a distance of several meters.

According to one or more example embodiments of the present invention, it can be provided that a map of the stray field generated by measurement and/or calculation is used as stray-field information, wherein the map describes a location-dependent, in particular absolute or normalized, gradient and/or a location-dependent level of the magnetic flux density of the stray field.

A stray magnetic field, which is generated by an apparatus, such as an MRI facility, basically has a gradient, i.e., the amplitude of the stray field or the magnetic flux density decreases with greater distance from the apparatus generating the magnetic field. The spatial profile of the stray field can be calculated or determined by measurement and displayed as a map, at least for a limited spatial region. Herein, the map can in particular assign the gradient and/or the magnetic flux density, in particular as a vector variable, to different distances from the apparatus in at least two, preferably three, spatial directions in each case, so that localization can, for example, take place relative to the apparatus.

An MRI facility can operate at different magnetic flux densities, for example at magnetic flux densities of 0.55 T, 1.5 T, 3 T or other values. Herein, it is possible for the stray-field information to represent the stray field in absolute values that are dependent on the flux density generated by the MRI facility. Additionally or alternatively, the stray field can also be indicated in normalized form, so that a determination of the position and/or orientation is, for example, ascertained from relative changes to at least two captured measured values.

In a preferred embodiment of the present invention, it can be provided that the measured value describes a local gradient of the stray field measured with the magnetic field sensor and/or a local magnetic flux density of the stray field measured with the magnetic field sensor. Depending on the embodiment of the magnetic field sensor, it is possible to capture a local gradient directly as a measured value, for example, or two measured values of the magnetic flux density captured at different positions or after a movement of the object can be used to determine a local gradient.

The magnetic flux density can in particular be measured vectorially by the magnetic field sensor. The ascertained local gradient and/or the ascertained local field strength can then be compared with the stray-field information so that it is possible to assign the measured value to at least one position or a subregion of the region covered by the stray-field information.

In a preferred embodiment of the present invention, it can be provided that a Hall sensor, which in particular ascertains magnetic flux density in three spatial directions, is used as a magnetic field sensor. A Hall sensor that ascertains magnetic flux density in three spatial directions, which can also be referred to as a three-dimensional or three-axis Hall sensor, can in particular ascertain at least one amplitude of a magnetic flux density along three spatial directions in each case. This in particular enables a vectorial determination of the magnetic flux density or possibly a determination of a gradient of the flux density.

According to one or more example embodiments of the present invention, it can be provided that a sensor facility comprising a plurality of magnetic field sensors arranged offset from one another is used, wherein the object information is ascertained in dependence on a plurality of measured values measured by the plurality of magnetic field sensors. Herein, a magnetic field sensor can be arranged at a plurality of locations on the object in each case, so that the measured values obtained in each case can be used to ascertain the position and the orientation of the object in a simple manner. In the case of an object embodied as a patient bench, the sensors can, for example, be arranged at the corners of the patient bench, so that they are spatially spaced apart. The use of a plurality of sensors in particular simplifies the ascertainment of a unique position or a unique orientation of the object, in particular if no further information, or only little further information, is used to ascertain the object information.

In a preferred embodiment of the present invention, it can be provided that the object is embodied to perform an automatic and/or semi-automatic movement operation at least in part of the region, in particular along a trajectory, wherein the object moves in dependence on the object information, and/or the object has a height-adjustment facility (or height-adjustment device) for automatically setting a height of the object, wherein the height of the object is set in dependence on the object information.

The movement of the object causes a change to the position of the magnetic field sensors within the stray field. Based on the positions and/or orientations of the object described in each case by in particular continuously ascertained object information, a control algorithm can be used, for example, to approach a target point or a target position successively at a predefined angle and/or to travel along a specified movement trajectory, so that the object can in particular be arranged relative to the apparatus.

The trajectory can, for example, be calculated in dependence on object information captured as a starting position or selected from a stored group of trajectories. During the movement operation, the object can move at least through part of the region in which the stray-field information indicates the stray field, since, for this region, it is possible to assign the measured value or measured values of the sensor facility via the stray-field information to a position or orientation of the object.

Additionally or alternatively to a moving facility (or movement device) for an automatic and/or semi-automatic movement operation, the object can also have a height-adjustment facility via which a height of the object, in particular a height of a bench surface or a patient table of an object embodied as a patient bench, can be set automatically. Herein, the setting can advantageously take place in dependence on the object information, which in particular can also include a height of the object or of the at least one magnetic field sensor, if, for example, a vertical component of the magnetic flux density and/or of the gradient of the stray field is ascertained.

The height of the object can, for example, be set automatically before, during and/or after a movement operation of the object. Setting the height in dependence on the object information advantageously enables the height to be set precisely, in particular the height of a table of an object embodied as a patient bench, so that the patient bench or the table of the patient bench can enter the bore of the MRI facility when docking with an MRI facility. This results in a workflow advantage that also minimizes the risk of raising the height close to the bore, for example a risk of crushing. Advantageously, the height of the object can be set automatically during a movement operation of the object, so that no extra time is required to set the height.

According to one or more example embodiments of the present invention, it can be provided that the object information is ascertained in dependence on region information describing part of the region that can be traversed by the object. If the part of the region that can be traversed by the object for which the stray-field information indicates the stray field is limited, for example due to other circumstances, such as an arrangement of further objects, walls or the like, the use of region information can improve the position determination by the magnetic field sensors, since regions that cannot be traversed by the object can already be excluded when ascertaining the position. Hence, this simplifies the assignment of a measured value to a specific position with the aid of the stray-field information, since in particular specific positions that are possible on the basis of the measured value can be excluded if they cannot be traversed by the object.

In a preferred embodiment of the present invention, it can be provided that the movement operation of the object takes place starting from a defined starting position in the region and/or starting from a defined starting subregion of the region, wherein the ascertainment of location information is restricted to the part of the region lying between the starting position and/or the starting subregion and a target position of the movement operation. Restricting the ascertainment of the object information to the part of the region lying between the starting position and/or the starting subregion and a target position of the movement operation reduces the search space for the ascertainment of the object information and hence simplifies navigation.

For example, an object embodied as an autonomously moving patient bench can be parked by an operator at a starting position or a starting subregion, wherein the patient bench independently approaches an apparatus embodied as an MRI facility as a target position with the aid of the object information in the automatic movement operation. Herein, it is, for example, possible for an operator only to push a patient on the patient bench into the entrance area of a magnet room in which the apparatus embodied as an MRI facility is located, and then to close the door and sit down at an operating console, while the patient bench automatically covers the last few meters to the MRI facility and in particular also performs the docking and/or entry to the MRI facility independently in the context of an automatic movement operation using the object information. This can result in time saving and accelerate the workflow, in particular in clinical applications in which a high throughput of examinations is to take place with an apparatus embodied as an MRI facility.

Herein, the entrance region of the magnet room represents the starting subregion of the region from which the movement operation is started. Alternatively, it is also possible to park at a defined and, for example, marked starting point, so that the movement operation can take place starting from this starting point. Herein, a region at the rear of the MRI facility can, for example, remain out of consideration as a target point or target position by restriction to the subregion between the starting region or the starting position and the MRI facility, since it can, for example, be located on the side facing away from the door, so that approaching the MRI facility from this region can be excluded.

In a preferred embodiment of the present invention, it can be provided that, in the movement operation, the object is brought closer to the apparatus, docks with the apparatus and/or enters the apparatus. In this way, preferably, an auto-docking function of an object embodied as an autonomously movable patient bench can be performed so that the patient bench can independently approach the apparatus embodied as an MRI facility and in particular also dock therewith and/or enter the apparatus, for example a bore of the MRI facility.

The ascertained object information enables the approach to take place in the correct position and at the correct angle. Advantageously, herein, the accuracy with which the object information can be ascertained increases as the distance to the MRI facility decreases, since the amplitude of the stray field increases ever more strongly and hence measurement tolerances of the magnetic field sensor become increasingly less important.

According to one or more example embodiments of the present invention, it can be provided that for at least part of the movement operation of the object, in particular in the immediate environment of the apparatus, a guide apparatus and/or a distance-ascertaining facility (or distance-ascertaining device) of the object is used. The guide apparatus can, for example, be rails or the like which the object enters in order to simplify docking with the apparatus in a defined position or to facilitate correct entry into the apparatus. The guide apparatus can, for example, be used to guide the object for the last 20 cm before complete docking.

Additionally or alternatively, a distance-ascertaining facility can also be used to increase the accuracy of the movement operation and/or the accuracy of the ascertainment of the object information, in particular in the immediate surroundings, for example in the last 20 cm before complete docking. The distance-ascertaining facility can also provide a collision-protection function. This is in particular advantageous, if the object, for example the patient bench, is also embodied for a movement operation outside the region and already comprises a distance-ascertaining facility for this purpose, for example a radar, lidar or ultrasonic sensor, a capacitive proximity sensor and/or a tactile sensor.

According to one or more example embodiments of the present invention, it can be provided that the object and/or the apparatus has at least one position-ascertaining facility (or position-ascertaining device) via which position information describing an at least approximate position and/or orientation of the object in at least one portion of the region is ascertained, wherein the object information is ascertained and/or validated in dependence on the position information.

For example, it can be provided that the object has a position-ascertaining facility, which also comprises an autonomous driving operation of the object outside the region in which navigation is possible with the aid of the stray field and the magnetic field sensors. Additionally or alternatively, the apparatus can also have a position-ascertaining facility that can additionally ascertain the position and/or orientation of an object within part of the region. This enables position information determined with the aid of the position-ascertaining facility to be used to ascertain the object information and/or object information only ascertained by the magnetic field sensors and the stray-field information to be validated with the aid of the position information.

The portion of the region in which the position information can be captured by the position-ascertaining facility does not have to be congruent with the part of the region in which the object is able to perform an automatic or semi-automatic movement operation; it is in particular possible that position information can also only be ascertained for a subregion of the movement range.

According to one or more example embodiments of the present invention, it can be provided that the position-ascertaining facility is an odometry facility (or odometry device) of the object and/or at least one surroundings-capturing facility (or surroundings-capturing device) of the object and/or the apparatus. Position information captured with the aid of an odometry facility can, for example, be a distance covered, which, in connection with a defined starting position and/or a defined starting subregion, as described above, enables an additional improvement to the accuracy of the ascertainment of the object information and/or the validation thereof. Additionally or alternatively, the position-ascertaining facility used can also be a surroundings-capturing facility such as all-round view cameras, conventional distance sensors such as ultrasonic sensors or the like. Herein, the surroundings-capturing facility can be part of the object or part of the apparatus and in particular also form or comprise the above-described distance-ascertaining facility.

According to one or more example embodiments of the present invention, it can be provided that a magnetic resonance imaging facility is used as the apparatus and/or that a patient bench and/or an accessory assigned to the magnetic resonance imaging facility is used as the object.

For an arrangement, according to one or more example embodiments of the present invention, it is provided that it comprises an apparatus, an object and a control facility (or controller), wherein the apparatus generates a stray magnetic field, the object has a sensor facility comprising at least one magnetic field sensor and the control facility is configured to perform a method, according to one or more example embodiments of the present invention, for localization of the object in the surroundings of the apparatus.

According to one or more example embodiments of the present invention, the control facility is therefore configured or embodied to ascertain at least one item of object information describing the position and/or orientation of the object in the region in dependence on stray-field information describing the spatial profile of the stray field at least within a region and at least one measured value measured with the sensor facility describing a location-dependent property of the stray field.

Herein, according to one or more example embodiments of the present invention, the control facility can be part of the apparatus, part of the object and/or a separate control facility, in particular one that at least communicates with the object.

The control facility is in particular configured to use a map of the stray field generated by measurement and/or calculation as stray-field information, wherein the map describes a location-dependent, in particular absolute or normalized, gradient and/or a location-dependent height of the flux density of the stray field.

According to one or more example embodiments of the present invention, herein, the measured value can describe a local gradient of the stray field measured with the magnetic field sensor and/or a local field strength of the stray field measured with the magnetic field sensor.

According to one or more example embodiments of the present invention, it can be provided that the magnetic field sensor is a Hall sensor, which in particular ascertains magnetic flux density in three spatial directions.

According to one or more example embodiments of the present invention, the object can comprise a sensor facility comprising a plurality of magnetic field sensors arranged offset from one another, wherein the object information can be ascertained in dependence on a plurality of measured values measured by the plurality of magnetic field sensors.

According to one or more example embodiments of the present invention, the object can be embodied to perform an automatic and/or semi-automatic movement operation in at least part of the region, in particular along a trajectory, wherein the object can be moved in dependence on the object information. Additionally or alternatively, the object can have a height-adjustment facility for automatically setting a height of the object, wherein the height of the object can be set in dependence on the object information.

According to one or more example embodiments of the present invention, herein, it can be provided that the object information can be ascertained in dependence on region information describing part of the region that can be traversed by the object.

According to one or more example embodiments of the present invention, it can be provided that the object is embodied to perform the movement operation starting from a defined starting position in the region and/or starting from a defined starting subregion of the region, wherein the ascertainment of the location information is restricted to the part of the region lying between the starting position and/or the starting subregion and a target position of the movement operation.

Furthermore, according to one or more example embodiments of the present invention, it can be provided that, in the movement operation, the object can be brought closer to the apparatus, dock with the apparatus and/or enter the apparatus.

According to one or more example embodiments of the present invention, it can be provided that the arrangement comprises a guide apparatus, which is embodied, for at least part of the movement operation of the object, in particular in the immediate environment of the apparatus, to guide a movement of the object and/or that the object has a distance-ascertaining facility, which, for at least part of the movement operation of the object, can in particular be used in the immediate environment of the apparatus.

In a preferred embodiment of the present invention, it can be provided that the object and/or the apparatus have at least one position-ascertaining facility via which position information describing an at least approximate position and/or orientation of the object can be ascertained in at least one portion of the region, wherein the control facility is configured to ascertain and/or validate the object information in dependence on the position information.

According to one or more example embodiments of the present invention, the position-ascertaining facility can be an odometry facility of the object and/or at least one surroundings-capturing facility of the object and/or the apparatus.

All the advantages and embodiments described above in relation to the method according to one or more example embodiments of the present invention also apply accordingly to the arrangement according to one or more example embodiments of the present invention and vice versa.

For an object according to one or more example embodiments of the present invention for an arrangement according to one or more example embodiments of the present invention, it is provided that the object is embodied as a patient bench or as an accessory assigned to an MRI facility.

All of the advantages and embodiments described above in relation to the method according to the present invention or the arrangement according to the present invention also apply accordingly to the object according to the present invention and vice versa.

### BRIEF DESCRIPTION OF THE DRAWINGS

Further advantages and details of the present invention will become apparent from the exemplary embodiments described in the following and with reference to the drawings. Herein, the drawings show:

FIG. 1 a schematic depiction of an exemplary embodiment of an arrangement according to the present invention in order to explain an exemplary embodiment of a method according to the present invention, and

FIG. 2 an exemplary embodiment of an object according to the present invention.

### DETAILED DESCRIPTION

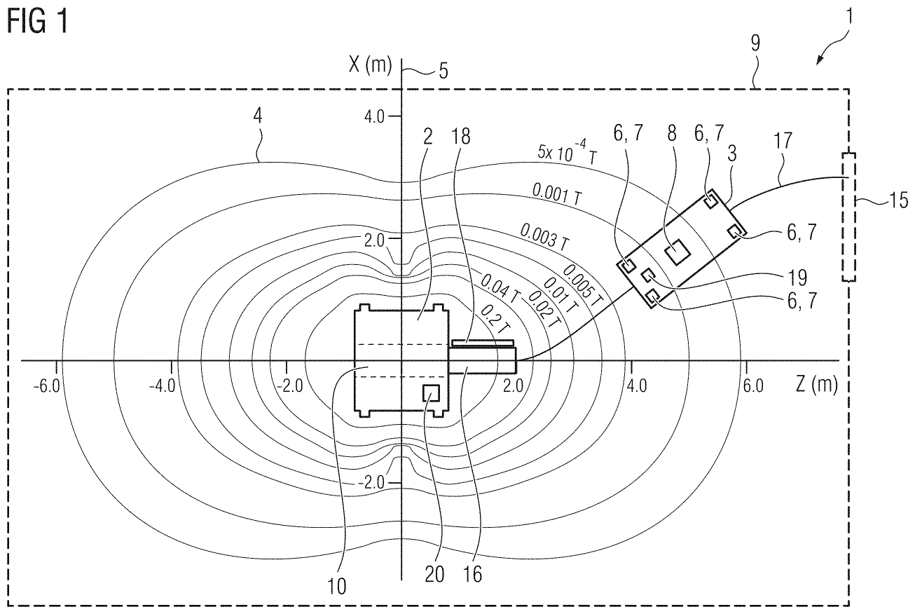

FIG. 1 depicts an exemplary embodiment of an arrangement 1 comprising an apparatus 2 and an object 3 in a top view. Herein, the apparatus 2 is embodied as a magnetic resonance imaging facility which generates a stray magnetic field 4. A plurality of field lines from the stray magnetic field 4 are drawn schematically and provided with associated magnetic flux densities by way of example. Furthermore, a coordinate system 5 is depicted in which the profile of field lines 4 is plotted in dependence on the location in the x-direction and z-direction relative to the apparatus 2 arranged around the origin of the coordinate systems 5.

The object 3 is embodied as a patient bench and arranged at a distance from the apparatus 2. The object 3 comprises a sensor facility 6, which has a plurality of magnetic field sensors 7. The object 3 furthermore comprises a control facility 8, which is configured to perform a method for localization of the object 3 in the surroundings of the apparatus 2 generating the stray field 4. For this purpose, the control facility 8 is connected to the magnetic field sensors 7 of the sensor facility 6, wherein, for the sake of clarity, the connections are not depicted in FIG. 1.

The control facility 8 can ascertain at least one item of object information describing the position and/or orientation of the object 3 in the region 9 in dependence on stray-field information describing the spatial profile of the stray field 4 at least within a region 9 around the apparatus 2 and at least one measured value measured with the sensor facility 6 describing a location-dependent property of the stray field 4. The region 9 is schematically depicted as a rectangular region around the apparatus 2 and can, for example, be a treatment room and/or examination room in which the apparatus 2 embodied as an MRI facility is arranged.

The magnetic field sensors 7 of the sensor facility 6 enable, for example, the recording of a measured value describing a local gradient of the stray field 4 and/or local magnetic flux density of the stray field 4. The stray-field information can also describe in particular a location-dependent, in particular absolute or normalized, gradient and/or a location-dependent level of the magnetic flux density of the stray field, as is schematically depicted for the field lines and the coordinate system 5 in FIG. 1.

The local field strengths of the stray field 4 measured, for example, by the four magnetic field sensors 7 in the present exemplary embodiment can be used to ascertain both the position of the object 3 and the orientation thereof in relation to the stray field 4 or in relation to the apparatus 2. For this purpose, the magnetic field sensors 7 are in particular embodied for a vectorial measurement of the magnetic field strengths. For example, the magnetic field sensors 7 can be embodied as three-dimensional Hall sensors or as Hall sensors that ascertain magnetic flux density in three spatial directions.

It is possible for the magnetic field sensors 7 to be embodied such that they are able to determine a local gradient of the stray field from a single measured value. Additionally or alternatively, the control facility 8 can also ascertain a local gradient from a plurality of values of the local magnetic flux density ascertained, for example, at different times during movement of the object 3. This, for example, enables an evaluation of a relative change in flux density in relation to a normalized gradient for the position determination, so that the determination of the position and/or orientation of the object 3 or the ascertainment of the object information can be used in the same way with MRI facilities which can generate scatter fields 4 at different absolute heights. Herein, it is, for example, possible to apply a gradient-optimization method as a search for local maxima in order to enable a determination of the position and/or orientation of the object 3, in particular during a movement of the object 3. Alternatively, the determination of the position and/or orientation, i.e., the ascertainment of the object information, can also take place based on absolute values assigned to the apparatus 2.

The stray field 4 generated by the MRI facility can depend on a maximum field strength that can be generated by the MRI facility inside a bore 10 representing the patient receptacle of the MRI facility and, for example, have different absolute values for magnetic flux density within the region 9 for MRI facilities that generate fields of, for example, 0.55 T, 1.5 T or 3 T. The use of a normalized gradient makes it possible to avoid the necessity of regulation to different absolute values when a determination of the position and/or orientation of the object 3 takes place, for example, in the course of a movement process of the object 3.

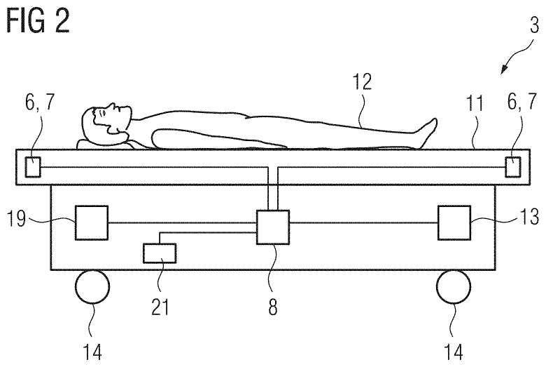

In FIG. 2 the object 3 embodied as a patient bench is depicted in a side view. The object 3 embodied as a patient bench comprises a patient bench surface 11 on which, in the present case, a patient 12 is arranged. In the present case, the magnetic field sensors 7 of the sensor facility 6 are arranged at the four corners of the patient bench surface 11. It is also possible to use a different number of magnetic field sensors 7, for example, three or more than four.

The object 3 is furthermore embodied to perform an automatic and/or semi-automatic movement operation, for which purpose, for example, the control facility 8 of the object 3 or a further control facility (not depicted) can actuate a moving facility 13 of the object 3, which can drive and/or steer rollers 14 of the object 3.

The object 3 is embodied to perform the movement process in dependence on the object information, which is obtained from the stray-field information stored, for example, in the control facility 8 and at least one measured value captured via the sensor facility 6. This enables the object 3 to be moved in a, in particular automatic or semi-automatic, movement process in the environment of the apparatus 2, without it being necessary to provide further environmental sensors as part of the object 3 for this purpose.

In order to enable the object information to be ascertained as precisely as possible, it can be provided that the object information is ascertained by the control facility 8 in dependence on region information describing part of the region 9 that can be traversed by the object 3. Herein, for the ascertainment of the position, the subregion of the region 9 in which it is at all possible for the object 3 to be located can be limited by the region information. This makes it possible, for example, to exclude from the outset as positions and/or orientations subregions which cannot be traversed by the object 3, for example because they are structurally blocked or blocked by further objects.

Furthermore, a defined starting position and/or a defined starting subregion of the region 9 can be taken into account for the determination of the orientation and/or position of the object 3 during the movement operation of the object 3. For example, it is possible that the movement of the object 3 always takes place starting from a starting region 15, depicted schematically in FIG. 1, in which, for example, a door of the region 9 embodied as a treatment room is located. For example, in everyday clinical practice, the patient bench can be moved manually into the starting region 15, wherein then an automatic movement process of the object 3 is carried out for approaching the apparatus 2 and/or docking with and/or entering the apparatus 2.

Advantageously, the ascertainment of the position and/or orientation of the object 3 can therefore take place taking into account the starting subregion 15, so that the ascertainment of the location information can be restricted to the part of the region lying between the starting subregion 15 and a target position 16 to be approached. Alternatively to a starting subregion 15, it is also possible to use a defined starting position, marked, for example, within the region 9 and stored in the control facility 8.

In the present exemplary embodiment, the ascertainment of the location information could, for example, be restricted to positive values for the z-direction, as a result of which the assignment of a, in particular vectorially measured, magnetic flux density and/or a local gradient to a position or an x-coordinate and a z-coordinate can be simplified and/or accelerated.

During the automatic and/or semi-automatic movement, the object 3 can be continuously moved using a plurality of object information items ascertained by the control facility 8. For example, a target position 16 of the movement can be a direct arrangement of the patient bench in front of the MRI facility. Additionally or alternatively, the autonomous movement operation can also include moving the patient bench into the bore 10 of the apparatus 2.

The object information determined with the aid of the magnet sensors 7 and the stray-field information can be used to move the object 3, for example along a trajectory 17 ascertained by the control facility 8 and/or stored in the control facility 8. Herein, the different magnetic flux densities or local magnetic gradients measured by the magnet sensor 7 enable the object 3 to be moved along the trajectory 17, for example by a control algorithm. Herein, a control algorithm used to move the object 3 can be embodied to be robust enough that it can compensate individual unavoidable deformations of the stray field 4, which can, for example, result from metal-reinforced walls of the treatment room or the like.

Advantageously, as depicted schematically by the exemplary values given for the magnetic flux density at the field lines, the measurable magnetic flux density in the immediate environment of the apparatus 2 increases steadily, so that the position and/or orientation can be determined with the aid of the object information with increasing precision the closer the object 3 moves to the apparatus 2.

Additionally or alternatively to the moving facility 13, the object 3 can also have a height-adjustment facility (not depicted) via which a height of the object 3, in particular a distance of the patient bench surface 11 or a patient table of an object 3 embodied as a patient bench from the floor that can be set automatically. Herein, the setting takes place in dependence on the object information, which, as part of the position of the object 3, also includes the height of the object 3 or the at least one magnetic field sensor 7, and possibly in dependence on a target height information describing a target height to be set, which can be stored in the control facility 8 and/or, in particular in dependence on the type of apparatus 2 to be approached, can be transmitted thereto. The height of the object 3 can, for example, be ascertained via a vertical component of the magnetic flux density and/or the gradient of the stray field 4 and accordingly set via the height-adjustment facility. Herein, the automatic setting of the height of the object 3 can advantageously take place during the movement operation of the object 3 so that the patient bench surface 11 can move directly into the bore 10 at the correct height when docking with the apparatus embodied as an MRI facility 2.

In order to additionally improve the precision of a docking process and/or entry process of the object 3 onto or into the apparatus 2, a guide apparatus 18 can be used, which, for example, comprises a rail or the like and mechanically guides a movement of the object 3, for example over the last 10 cm to 50 cm in front of the apparatus 2, in order to enable precise docking and/or entry of the object 3 into the apparatus 2.

Additionally or alternatively, a distance-ascertaining facility 21 of the object 3 can be used for docking and/or for collision avoidance during docking. The distance-ascertaining facility 21 can, for example, comprise a radar, lidar or ultrasonic sensor, capacitive proximity sensor or tactile sensor. Herein, in the immediate vicinity of the object, the movement process can be performed in dependence on distance information ascertained by the distance-ascertaining facility 21 and/or by ascertaining the object information used for the movement operation additionally in dependence on the distance information.

Additionally or alternatively, it is possible for the object 3 and/or the apparatus 2 to comprise at least one position-ascertaining facility 19, 20. Herein, the position-ascertaining facility 19 of the object 3 can, for example, be embodied as an odometry facility. The position-ascertaining facility 20 of the apparatus 2 and/or the position-ascertaining facility 19 or a further position-ascertaining facility 19 of the object 3 can also be embodied as a surroundings-capturing facility.

Herein, for example, an all-round view camera can be used as the surroundings-capturing facility. The surroundings-capturing facility can additionally or alternatively also comprise the distance-ascertaining facility 21 or form the distance-ascertaining facility 21 of the object 3. In the case of a position-ascertaining facility 20 used as part of the apparatus 2, it can communicate with the control facility 8 of the object 3, in particular wirelessly, so that position information ascertained with the aid of the position-ascertaining facility 20 of the apparatus 2 describing an at least approximate position and/or orientation of the object 3 in at least one portion of the region 9 can be transmitted to the control facility 8 and used thereby to ascertain and/or validate the object information.

Accordingly, the position-ascertaining facility 19 of the object 3 can communicate with the control facility 8, so that accordingly position information ascertained by this position-ascertaining facility 19 can likewise be used to ascertain the object information and/or for its validation. A position-ascertaining facility 19 of the object 3 embodied, for example, as an odometry facility can, for example, be used to ascertain at least the approximate entry position into the region 9 and hence, for example, to determine a starting subregion 15 if this is not permanently provided and/or stored in the control facility 8.

It is possible for the control facility 8 not to be embodied as part of the object 3, but to be part of the apparatus 2 and/or as a separately arranged control facility that communicates with the object 3, and possibly also with the apparatus 2.

Furthermore, it is possible also to use the ascertainment of the position and/or orientation of the object 3 for another type of object 3 in the surroundings of an apparatus 2 embodied in particular as a magnetic resonance imaging facility. The object 3 can, for example, be embodied as an accessory assigned to a magnetic resonance imaging facility. Furthermore, it is also possible to use a corresponding method in the surroundings of a different type of apparatus 2, which also generates a stray field 4.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “on,” “connected,” “engaged,” “interfaced,” and “coupled.” Unless explicitly described as being “direct,” when a relationship between first and second elements is described in the disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” on, connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “example” is intended to refer to an example or illustration.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

It is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed above. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments. The present invention may, however, be embodied in many alternate forms and should not be construed as limited to only the embodiments set forth herein.

In addition, or alternative, to that discussed above, units and/or devices according to one or more example embodiments may be implemented using hardware, software, and/or a combination thereof. For example, hardware devices may be implemented using processing circuity such as, but not limited to, a processor, Central Processing Unit (CPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as a computer processing device or processor; however, one skilled in the art will appreciate that a hardware device may include multiple processing elements or processors and multiple types of processing elements or processors. For example, a hardware device may include multiple processors or a processor and a controller. In addition, other processing configurations are possible, such as parallel processors.

The computer programs include processor-executable instructions that are stored on at least one non-transitory computer-readable medium (memory). The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc. As such, the one or more processors may be configured to execute the processor executable instructions.

The computer programs may include: (i) descriptive text to be parsed, such as HTML (hypertext markup language) or XML (extensible markup language), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Haskell, Go, SQL, R, Lisp, Java®, Fortran, Perl, Pascal, Curl, OCaml, Javascript®, HTML5, Ada, ASP (active server pages), PHP, Scala, Eiffel, Smalltalk, Erlang, Ruby, Flash®, Visual Basic®, Lua, and Python®.

Further, at least one example embodiment relates to the non-transitory computer-readable storage medium including electronically readable control information (processor executable instructions) stored thereon, configured in such that when the storage medium is used in a controller of a device, at least one embodiment of the method may be carried out.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

Although the present invention has been illustrated and described in greater detail by the preferred exemplary embodiments, the present invention is not restricted by the disclosed examples and other variations can be derived herefrom by the person skilled in the art without departing from the scope of protection of the present invention.

What is claimed is:

1. A method for localizing an object in surroundings of an apparatus generating a stray magnetic field, the object having a sensor arrangement including at least one magnetic field sensor, the method comprising:
ascertaining at least one item of object information based on (i) stray-field information describing a spatial profile of the stray magnetic field at least within a region and (ii) at least one measured value measured with the sensor arrangement describing a location-dependent property of the stray magnetic field, the at least one item of object information describing at least one of a position or an orientation of the object in the region.

2. The method as claimed in claim 1, wherein
the stray-field information includes a map of the stray magnetic field generated by at least one of measurement or calculation, and
the map describes at least one of a location-dependent gradient or a location-dependent level of a magnetic flux density of the stray magnetic field.

3. The method as claimed in claim 1, wherein the at least one measured value describes at least one of a local gradient of the stray magnetic field measured with the at least one magnetic field sensor or a local magnetic flux density of the stray magnetic field measured with the at least one magnetic field sensor.

4. The method as claimed in claim 1, wherein the at least one magnetic field sensor is a Hall sensor configured to ascertain magnetic flux density in three spatial directions.

5. The method as claimed in claim 1, wherein
the sensor arrangement includes a plurality of magnetic field sensors arranged offset from one another, and
the ascertaining ascertains the at least one item of object information based on a plurality of measured values measured by the plurality of magnetic field sensors.

6. The method as claimed in claim 1, wherein at least one of
the object is configured to perform at least one of an automatic or semi-automatic movement operation along a trajectory at least in part of the region, wherein the object is moved based on the object information, or
the object has a height-adjustment device configured to automatically set a height of the object, wherein the height of the object is set based on the object information.

7. The method as claimed in claim 6, wherein the ascertaining ascertains the at least one item of object information based on region information describing a part of the region traversable by the object.

8. The method as claimed in claim 6, wherein the movement operation of the object starts from at least one of a defined starting position in the region or from a defined starting subregion of the region, wherein ascertaining of the position is restricted to a part of the region between a target position of the movement operation and the at least one of the defined starting position or the defined starting subregion.

9. The method as claimed in claim 6, wherein, in the movement operation, the object at least one of (i) is moved closer to the apparatus, (ii) docks with the apparatus or (iii) enters the apparatus.

10. The method as claimed in claim 6, wherein, for at least part of the movement operation of the object, at least one of a guide apparatus or a distance-ascertaining device of the object is used.

11. The method as claimed in claim 1, wherein
at least one of the object or the apparatus has at least one position-ascertaining device by which position information describing at least one of an at least approximate position or orientation of the object is ascertained in at least one portion of the region, and
the at least one item of object information is at least one of ascertained or validated based on the position information.

12. The method as claimed in claim 11, wherein the at least one position-ascertaining device includes at least one of an odometry device of the object, at least one surroundings-capturing device of the object, or the apparatus.

13. The method as claimed in claim 1, wherein at least one of
the apparatus is an MRI device, or
the object includes at least one of a patient bench or an accessory assigned to the MRI device.

14. An arrangement comprising:
an apparatus configured to generate a stray magnetic field;
an object having a sensor arrangement including at least one magnetic field sensor; and
a controller configured to perform the method as claimed in claim 1.

15. The arrangement as claimed in claim 14, wherein the object is a patient bench or an accessory assigned to an MRI device.

16. An arrangement comprising:
an apparatus configured to generate a stray magnetic field;
an object having a sensor arrangement including at least one magnetic field sensor; and
a controller configured to
ascertain at least one item of object information based on (i) stray-field information describing a spatial profile of the stray magnetic field at least within a region and (ii) at least one measured value measured with the sensor arrangement describing a location-dependent property of the stray magnetic field, the at least one item of object information describing at least one of a position or an orientation of the object in the region.

17. The method as claimed in claim 2, wherein the location-dependent gradient is an absolute or normalized gradient.

18. The method as claimed in claim 10, wherein, in immediate surroundings of the apparatus, the at least one of the guide apparatus or the distance-ascertaining device of the object is used for the movement operation of the object.

19. The method as claimed in claim 7, wherein the movement operation of the object starts from at least one of a defined starting position in the region or from a defined starting subregion of the region, wherein ascertaining of the position is restricted to a part of the region between a target position of the movement operation and the at least one of the defined starting position or the defined starting subregion.

20. The method as claimed in claim 2, wherein
the sensor arrangement includes a plurality of magnetic field sensors arranged offset from one another, and
the ascertaining ascertains the at least one item of object information based on a plurality of measured values measured by the plurality of magnetic field sensors.
